(19) United States
(12) Patent Application Publication
(10) Pub. No.: US 2025/0110327 A1
(43) Pub. Date: Apr. 3, 2025

(54) METHOD FOR OPERATING A CONTROL DEVICE, CONTROL DEVICE, OPTICAL SYSTEM AND LITHOGRAPHY APPARATUS

(71) Applicant: Carl Zeiss SMT GmbH, Oberkochen (DE)

(72) Inventor: Cornelius Richt, Aalen (DE)

(21) Appl. No.: 18/891,383

(22) Filed: Sep. 20, 2024

(30) Foreign Application Priority Data
Sep. 28, 2023 (DE) 10 2023 209 509.2

(51) Int. Cl. G02B 26/08; G01R 19/00; G01R 31/52; G02B 26/10; G03F 7/20

(52) U.S. Cl. CPC G02B 26/0816; G01R 19/0084; G01R 31/52; G03F 7/2004; G02B 26/101

(57) ABSTRACT

A method of operating a control device for controlling and measuring a plurality N of actuators for actuating at least one optical element of an optical system comprises measuring an individual actuator of the N actuators during a specific measurement time interval. The measurement is carried by exciting the individual actuator via an excitation voltage provided by a control unit. A measurement current indicative of a time-dependent current of the actuator excited via the excitation voltage is provided by a current measuring unit. A measurement voltage indicative of a time-dependent voltage of the actuator excited via the excitation voltage is provided by a voltage measuring unit. An impedance measurement result is ascertained based on the provided measurement current and the provided measurement voltage. A deviation indicative of a fault in the control device is determined based on the ascertained impedance measurement result.

### CROSS-REFERENCE TO RELATED APPLICATIONS

This application claims benefit under 35 U.S.C. § 119 to German Application No. 10 2023 209 509.2, filed Sep. 28, 2023. The entire disclosure of this application is incorporated by reference herein.

### FIELD

The present disclosure relates to a method for operating a control device for controlling and measuring a plurality of actuators for actuating at least one optical element of an optical system, to a control device for controlling and measuring a plurality of actuators for actuating at least one optical element of an optical system, to an optical system having such a control device, and to a lithography apparatus having such an optical system.

### BACKGROUND

Microlithography apparatuses are known which have actuatable optical elements, such as, for example, microlens element arrays or micromirror arrays. Microlithography is used to produce microstructured component parts, for example integrated circuits. The microlithography process is carried out using a lithography apparatus comprising an illumination system and a projection system.

Driven by the desire for ever smaller structures in the production of integrated circuits, EUV lithography apparatuses that use light with a wavelength in the range from 0.1 nm to 30 nm, such as 13.5 nm, are currently under development. Since, in general, most materials absorb light of this wavelength, such EUV lithography apparatuses typically use reflective optics, i.e. mirrors, instead of—as previously—refractive optics, i.e. lens elements.

The image of a mask (reticle) illuminated via the illumination system is projected here via the projection system onto a substrate, for example a silicon wafer, which is coated with a light-sensitive layer (photoresist) and arranged in the image plane of the projection system, in order to transfer the mask structure to the light-sensitive coating of the substrate. The image representation of the mask on the substrate is able to be improved by way of actuatable optical elements. For example, wavefront aberrations during exposure, which result in magnified and/or blurred image representations, are able to be compensated for.

Such correction via the optical element involves detection of the wavefront and signal processing in order to ascertain a respective position of an optical element which enables the wavefront to be corrected as desired. In the last step, the control signal for a respective optical element is amplified and output to the actuator of the optical element.

For example, a PMN actuator (PMN; lead magnesium niobate) can be used as actuator. A PMN actuator can enable distance positioning in the sub-micrometre range or sub-nanometre range. In this case, a DC voltage applied to the actuator, which has actuator elements stacked one on top of another, leads to it experiencing a force that causes a specific linear expansion. The position set by way of the DC voltage (DC; Direct Current) can be adversely affected by external electromechanical crosstalk at the resonance points of the actuator controlled by the DC voltage which arise as a matter of principle. Owing to this electromechanical crosstalk, precise positioning might no longer able to be set in a stable manner. In this case, the mechanical resonances are generally all the greater the higher the applied DC voltage. The resonance points may also change in the long term, for example as a result of temperature drift or as a result of adhesive drift if the mechanical linking of the adhesive material changes, or as a result of hysteresis or ageing. For example, an impedance measurement is helpful in this context.

Certain conventional solutions for measuring the impedance of a plurality of actuators in an optical system successively carry out impedance measurements for the individual actuators. In this respect, FIG. 7 shows a schematic block diagram of such a conventional control device 400 for measuring a plurality N of actuators 201-225 for actuating at least one optical element of an optical system. For example, N equals 25 (N=25).

As shown in FIG. 7, the control device 400 has a control unit 410 and a switching matrix 420. Moreover, ZD denotes the impedance of a potential defect in the control device 400 between the output of the actuators 201-225 and a common negative electrode 430, and ZZ denotes the impedance of the feed line, which connects the common electrode 430 to a current measuring unit (not depicted here). In this case, the switching matrix 420 is configured to connect only the actuator to be measured, the actuator 201 in the example of FIG. 7, to the control unit 410. If the actuator 201 has been measured, the control matrix 420 can connect the next actuator 202 to the control unit 410. Thus, the switching matrix 420 of FIG. 7 can help ensure that only an individual actuator, for example the actuator 201, is connected to the control unit 410 at any one time and that the remaining actuators 202-225 are not contacted. During the impedance measurement, the impedance of the feed line ZZ and the impedance ZD of a potential defect in the control device 400 can then be rendered visible with a factor of 1. Thus, changes are not amplified.

Measuring the individual actuators 202-225 in succession can involve disconnection of the further N−1 actuators. Consequently, the measurement of the actuators 201-225 according to FIG. 7 is not possible during the ongoing operation of the optical system. Additionally, the detection of circuit defects on the common reference potential line is only detectable in the case of relatively large defects on account of a low impedance.

### SUMMARY

The present disclosure seeks to improve the measurement of an actuator in an optical system.

According to a first aspect, a method is proposed for operating a control device for controlling and measuring a plurality N of actuators for actuating at least one optical element of an optical system. In the process, an individual actuator to be measured from the N actuators is measured during a specific measurement time interval, the measurement being carried out by virtue of the actuator to be measured being excited via an excitation voltage provided by a control unit, a measurement current indicative of a time-dependent current of the actuator excited via the excitation voltage being provided by a current measuring unit, a measurement voltage indicative of a time-dependent voltage of the actuator excited via the excitation voltage being provided by a voltage measuring unit, an impedance measurement result being ascertained on the basis of the provided measurement current and the provided measurement voltage and a deviation indicative of a fault in the control device being determined on the basis of the ascertained impedance measurement result, wherein the N−1 further actuators of the N actuators are kept at a specific voltage level while the actuator to be measured is excited via the excitation voltage.

As a result of the N−1 further actuators being kept at a specific voltage level while the actuator to be measured is being measured, a portion of the excitation current can flow into the N−1 further actuators as fault current. This falsifies the impedance measurement of the actuator to be measured and, by a factor of N−1, makes it more sensitive to change, for example with regard to the feed line impedance of the feed line to the current measuring unit.

As a result of the present impedance measurement being substantially more sensitive, it is possible to detect faults at a lower impedance and, for example, with greater reliability. In detail, the higher sensitivity of the present impedance measurement renders the detection of circuit defects on the common reference potential line of the N actuators detectable even in the case of relatively small defects. The effect of a defect on the common reference potential line is presently amplified by a factor of N−1. As a result, detection is already possible even in the case of small faults.

For example, N=25. In this case, the present impedance measurement is 24-times more sensitive than the case of a conventional impedance measurement, for example as depicted in FIG. 7. Using a small signal equivalent circuit diagram, the example of FIG. 6 explained below illustrates for the example N=25 that the present impedance measurement is more sensitive by a factor of 24.

Suitable remedies or countermeasures, for example an active inline calibration or inline damping, can be taken up on the basis of the ascertained impedance measurement result of the actuator or on the basis of the determined deviation. The present impedance measurement serves health monitoring purposes for example, especially for ensuring the signal transmission quality in connection transitions in this case.

For example, the actuator is a capacitive actuator, for example a PMN actuator (PMN; lead magnesium niobate) or a PZT actuator (PZT; lead zirconate titanate) or a LiNbO₃ actuator (lithium niobate). The actuator is configured, for example, to actuate an optical element of the optical system. Examples of such an optical element include lens elements, mirrors and adaptive mirrors.

The optical system can be a projection optical unit of the lithography apparatus or projection exposure apparatus. However, the optical system can also be an illumination system. The projection exposure apparatus can be an EUV lithography apparatus. EUV stands for “extreme ultraviolet” and refers to a wavelength of the working light of between 0.1 nm and 30 nm. The projection exposure apparatus can also be a DUV lithography apparatus. DUV stands for “deep ultraviolet” and refers to a wavelength of the working light of between 30 nm and 250 nm.

According to an embodiment, the actuator to be measured is measured during the ongoing operation of the optical system. An aspect herein is found in the fact that the optical system need not additionally be put into a diagnostic mode especially in order to carry out the impedance measurement on the actuator to be measured. Instead, the impedance measurement is in this case carried out during the ongoing operation of the optical system.

According to an embodiment, the N−1 further actuators are kept at a specific hold voltage while the actuator to be measured is excited via the excitation voltage.

According to an embodiment, the specific hold voltages of the N−1 further actuators are identical. The hold voltage can also be referred to as bias voltage.

According to an embodiment, the N−1 further actuators are short-circuited while the actuator to be measured is excited via the excitation voltage.

According to an embodiment, the N actuators are connected at a common negative electrode. As a result of the present impedance measurement, it is possible to ascertain the correct functioning of the common negative electrode during the operation of the optical system, whereby outages can be avoided.

According to an embodiment, the current measuring unit for providing the measurement current indicative of the time-dependent current of the actuator excited via the excitation voltage is coupled between the negative electrode of the N actuators and the N control units for the N actuators.

According to an embodiment, the voltage measuring unit for providing the measurement voltage is connected in parallel with the actuator to be measured.

According to an embodiment, the voltage measuring unit for providing the measurement voltage is coupled with the control unit associated with the actuator to be measured. In this case, the measurement voltage for ascertaining the impedance measurement result can be derived from the excitation voltage.

According to an embodiment, the N actuators and the common negative electrode are formed as part of an actuator pad.

According to an embodiment, the control unit comprises an amplifier circuit, for example a differential amplifier.

According to a second aspect, a control device is proposed for controlling and measuring a plurality N of actuators for actuating at least one optical element of an optical system. The control device comprises a controller configured to control a measurement of an individual actuator to be measured from the N actuators during a specific measurement time interval, a control unit controlled by the controller and configured to excite, using an excitation voltage, the actuator to be measured, a current measuring unit for providing a measurement current indicative of a time-dependent current of the actuator excited via the excitation voltage, and a voltage measuring unit for providing a measurement voltage indicative of a time-dependent voltage of the actuator excited via the excitation voltage. In this case, the controller is configured to control that the N−1 further actuators of the N actuators are kept at a specific voltage level while the actuator to be measured is excited via the excitation voltage. The controller is further configured to ascertain an impedance measurement result on the basis of the provided measurement current and the provided measurement voltage and determine a deviation indicative of a fault in the control device on the basis of the ascertained impedance measurement result.

The N actuators can be connected at a common negative electrode.

The embodiments described for the proposed method are valid correspondingly for the proposed control device, and vice versa. Furthermore, the definitions and explanations in relation to the method also apply correspondingly to the proposed control device.

The respective unit, for example the controller, can be implemented by way of hardware technology and/or also software technology. In the case of a hardware implementation, the unit can be in the form of a device or part of a device, for example a computer or a microprocessor or part of the control apparatus. In the case of a software implementation, the unit can be in the form of a computer program product, a function, a routine, part of a program code or an executable object.

According to a third aspect, an optical system having a number of actuatable optical elements is proposed, wherein each of the actuatable optical elements is assigned a number of actuators which are associated with a control device for controlling the actuators according to the second aspect or according to one of the embodiments of the second aspect.

The optical system comprises, for example, a micromirror array and/or a microlens element array having a multiplicity of optical elements that are actuatable independently of one another.

In embodiments, groups of actuators can be defined, wherein all actuators of a group are assigned the same control device.

According to an embodiment, the optical system is in the form of an illumination optical unit or in the form of a projection optical unit of a lithography apparatus.

According to an embodiment, the optical system comprises a vacuum housing, in which the actuatable optical elements, the assigned actuators and the control device are arranged.

According to a fourth aspect, a lithography apparatus is proposed, which comprises an optical system according to the third aspect or according to one of the embodiments of the third aspect.

The lithography apparatus is for example an EUV lithography apparatus, the working light of which is in a wavelength range of 0.1 nm to 30 nm, or a DUV lithography apparatus, the working light of which is in a wavelength range of 30 nm to 250 nm.

“A(n)” should not necessarily be understood as a restriction to exactly one element in the present case. Rather, a plurality of elements, for example two, three or more, may also be provided. Nor should any other numeral used here be understood to the effect that there is a restriction to exactly the stated number of elements. Rather, unless indicated otherwise, numerical deviations upward and downward are possible.

Further possible implementations of the disclosure also encompass not explicitly mentioned combinations of features or embodiments that are described above or hereinafter with respect to the exemplary embodiments. In this case, a person skilled in the art will also add individual aspects as improvements or supplementations to the respective basic form of the disclosure.

Further features, configurations and aspects of the disclosure are the subject matter of the dependent claims and also of the exemplary embodiments of the disclosure that are described below. The disclosure is explained in greater detail hereinafter on the basis of embodiments with reference to the accompanying figures.

### BRIEF DESCRIPTION OF THE DRAWINGS

FIG. 1 shows a schematic meridional section of a projection exposure apparatus for EUV projection lithography;

FIG. 2 shows a schematic illustration of an embodiment of an optical system;

FIG. 3 shows a schematic view of an embodiment of a method for controlling and measuring a plurality of actuators for actuating at least one optical element of an optical system;

FIG. 4 shows a schematic block diagram of a first embodiment of a control device for controlling and measuring a plurality of actuators for actuating at least one optical element of an optical system;

FIG. 5 shows a schematic block diagram of a second embodiment of a control device for controlling and measuring a plurality of actuators for actuating at least one optical element of an optical system;

FIG. 6 shows a small signal equivalent circuit diagram of an embodiment of a control device for controlling and measuring a plurality of actuators for actuating at least one optical element of an optical system; and

FIG. 7 shows a schematic block diagram of a conventional control device for measuring a plurality of actuators for actuating at least one optical element of an optical system.

### DETAILED DESCRIPTION

Unless indicated otherwise, elements that are identical or functionally identical have been provided with the same reference signs in the figures. Furthermore, it should be noted that the illustrations in the figures are not necessarily true to scale.

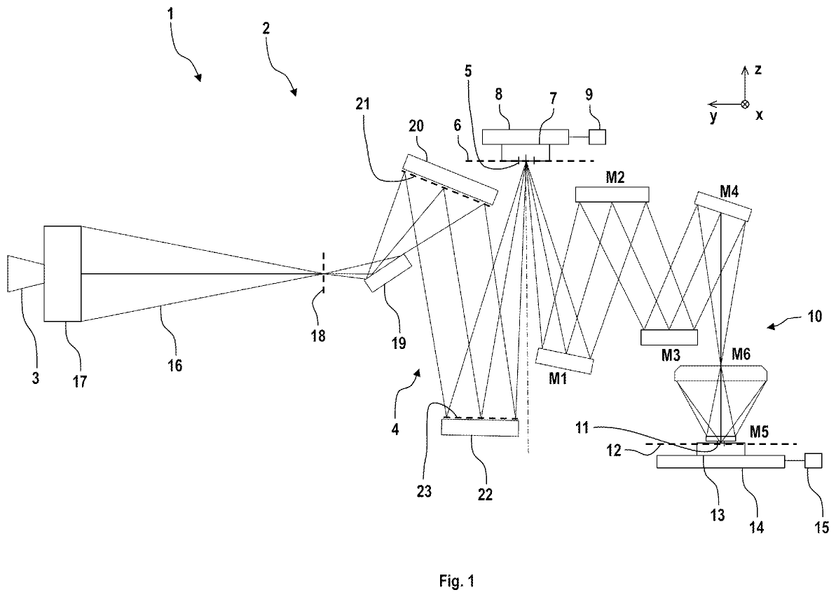

FIG. 1 shows one embodiment of a projection exposure apparatus 1 (lithography apparatus), for example an EUV lithography apparatus. One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 can also be provided as a module separate from the rest of the illumination system 2. In this case, the illumination system 2 does not comprise the light source 3.

A reticle 7 arranged in the object field 5 is exposed. The reticle 7 is held by a reticle holder 8. The reticle holder 8 is displaceable by way of a reticle displacement drive 9, for example in a scanning direction.

FIG. 1 shows, for explanatory purposes, a Cartesian coordinate system with an x-direction x, a y-direction y and a z-direction z. The x-direction x runs perpendicularly into the plane of the drawing. The y-direction y runs horizontally, and the z-direction z runs vertically. The scanning direction in FIG. 1 runs in the y-direction y. The z-direction z runs perpendicularly to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. As an alternative, an angle that differs from 0° between the object plane 6 and the image plane 12 is also possible.

A structure on the reticle 7 is imaged on a light-sensitive layer of a wafer 13 arranged in the region of the image field 11 in the image plane 12. The wafer 13 is held by a wafer holder 14. The wafer holder 14 is displaceable by way of a wafer displacement drive 15, for example in the y-direction y. The displacement firstly of the reticle 7 by way of the reticle displacement drive 9 and secondly of the wafer 13 by way of the wafer displacement drive 15 can be implemented so as to be mutually synchronized.

The light source 3 is an EUV radiation source. The light source 3 emits for example EUV radiation 16, which is also referred to below as used radiation, illumination radiation or illumination light. For example, the used radiation 16 has a wavelength in the range between 5 nm and 30 nm. The light source 3 can be a plasma source, for example an LPP (laser produced plasma) source or a GDPP (gas discharge produced plasma) source. It can also be a synchrotron-based radiation source. The light source 3 can be a free electron laser (FEL).

The illumination radiation 16 emanating from the light source 3 is focused by a collector 17. The collector 17 can be a collector with one or more ellipsoidal and/or hyperboloidal reflection surfaces. The illumination radiation 16 can be incident on the at least one reflection surface of the collector 17 with grazing incidence (GI), i.e. at angles of incidence of greater than 45°, or with normal incidence (NI), i.e. at angles of incidence of less than 45°. The collector 17 may be structured and/or coated, both to optimize its reflectivity for the used radiation and to suppress extraneous light.

Downstream of the collector 17, the illumination radiation 16 propagates through an intermediate focus in an intermediate focal plane 18. The intermediate focal plane 18 can represent a separation between a radiation source module, comprising the light source 3 and the collector 17, and the illumination optical unit 4.

The illumination optical unit 4 comprises a deflection mirror 19 and, arranged downstream thereof in the beam path, a first facet mirror 20. The deflection mirror 19 can be a plane deflection mirror or, alternatively, a mirror with a beam-influencing effect going beyond the pure deflection effect. In an alternative to that or in addition, the deflection mirror 19 can be designed as a spectral filter that separates a used light wavelength of the illumination radiation 16 from extraneous light at a different wavelength.

If the first facet mirror 20 is arranged in a plane of the illumination optical unit 4 that is optically conjugate to the object plane 6 as a field plane, it is also referred to as a field facet mirror. The first facet mirror 20 comprises a multiplicity of individual first facets 21, which can also be referred to as field facets. Only some of these first facets 21 are shown in FIG. 1 by way of example.

The first facets 21 can be embodied as macroscopic facets, for example as rectangular facets or as facets with an arcuate or part-circular edge contour. The first facets 21 can be in the form of plane facets or alternatively in the form of convexly or concavely curved facets.

As is known for example from DE 10 2008 009 600 A1, the first facets 21 themselves can also each be composed of a multiplicity of individual mirrors, for example a multiplicity of micromirrors. For example, the first facet mirror 20 can be in the form of a microelectromechanical system (MEMS system). For details, reference is made to DE 10 2008 009 600 A1.

The illumination radiation 16 propagates horizontally, i.e. in the y-direction y, between the collector 17 and the deflection mirror 19.

In the beam path of the illumination optical unit 4, a second facet mirror 22 is disposed downstream of the first facet mirror 20. Provided the second facet mirror 22 is arranged in a pupil plane of the illumination optical unit 4, it is also referred to as a pupil facet mirror. The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 can likewise be macroscopic facets, which can, for example, have a round, rectangular or else hexagonal boundary, or alternatively be facets composed of micromirrors. In this regard, reference is again made to DE 10 2008 009 600 A1.

The second facets 23 can have plane reflection surfaces or, alternatively, convexly or concavely curved reflection surfaces.

The illumination optical unit 4 thus forms a double-faceted system. This fundamental principle is also referred to as a fly's eye integrator.

It may be desirable to arrange the second facet mirror 22 not exactly within a plane that is optically conjugate to a pupil plane of the projection optical unit 10. For example, the second facet mirror 22 can be arranged so as to be tilted in relation to a pupil plane of the projection optical unit 10, as is described for example in DE 10 2017 220 586 A1.

With the aid of the second facet mirror 22, the individual first facets 21 are imaged into the object field 5. The second facet mirror 22 is the last beam-shaping mirror or else indeed the last mirror for the illumination radiation 16 in the beam path upstream of the object field 5.

In a further embodiment (not illustrated) of the illumination optical unit 4, a transfer optical unit contributing for example to the imaging of the first facets 21 into the object field 5 can be arranged in the beam path between the second facet mirror 22 and the object field 5. The transfer optical unit can have exactly one mirror or, alternatively, two or more mirrors, which are arranged in succession in the beam path of the illumination optical unit 4. The transfer optical unit may for example comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the first facet mirror 20, and the second facet mirror 22.

In a further embodiment of the illumination optical unit 4, the deflection mirror 19 can also be omitted, and so the illumination optical unit 4 can then have exactly two mirrors downstream of the collector 17, specifically the first facet mirror 20 and the second facet mirror 22.

The imaging of the first facets 21 into the object plane 6 via the second facets 23 or using the second facets 23 and a transfer optical unit is routinely only approximate imaging.

The projection optical unit 10 comprises a plurality of mirrors Mi, which are consecutively numbered in accordance with their arrangement in the beam path of the projection exposure apparatus 1.

In the example shown in FIG. 1, the projection optical unit 10 comprises six mirrors M1 to M6. Alternatives with four, eight, ten, twelve or any other number of mirrors Mi are likewise possible. The projection optical unit 10 is a twice-obscured optical unit. The penultimate mirror M5 and the last mirror M6 each have a passage opening for the illumination radiation 16. The projection optical unit 10 has an image-side numerical aperture that is greater than 0.5 and can also be greater than 0.6 and can be for example 0.7 or 0.75.

Reflection surfaces of the mirrors Mi can be in the form of free-form surfaces without an axis of rotational symmetry. Alternatively, the reflection surfaces of the mirrors Mi can be in the form of aspherical surfaces with exactly one axis of rotational symmetry of the reflection surface shape. Just like the mirrors of the illumination optical unit 4, the mirrors Mi can have highly reflective coatings for the illumination radiation 16. These coatings can be designed as multilayer coatings, for example with alternating layers of molybdenum and silicon.

The projection optical unit 10 has a large object-image offset in the y-direction y between a y-coordinate of a centre of the object field 5 and a y-coordinate of the centre of the image field 11. This object-image offset in the y-direction y can be of approximately the same magnitude as a z-distance between the object plane 6 and the image plane 12.

For example, the projection optical unit 10 can have an anamorphic design. It has for example different imaging scales βx, βy in the x- and y-directions x, y. The two imaging scales βx, βy of the projection optical unit 10 can be (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction x, i.e. in a direction perpendicular to the scanning direction.

The projection optical unit 10 leads to a reduction in size of 8:1 in the y-direction y, i.e. in the scanning direction.

Other imaging scales are likewise possible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 can be the same or can differ, depending on the embodiment of the projection optical unit 10. Examples of projection optical units with different numbers of such intermediate images in the x- and y-directions x, y are known from US 2018/0074303 A1.

In each case, one of the second facets 23 is assigned to exactly one of the first facets 21 for forming in each case an illumination channel for illuminating the object field 5. This can for example result in illumination according to the Köhler principle. The far field is decomposed into a multiplicity of object fields 5 with the aid of the first facets 21. The first facets 21 create a plurality of images of the intermediate focus on the second facets 23 respectively assigned to them.

βy way of an assigned second facet 23, the first facets 21 are in each case imaged onto the reticle 7 in a manner overlaid on one another for the purpose of illuminating the object field 5. The illumination of the object field 5 is for example as homogeneous as possible. It can have a uniformity error of less than 2%. Field uniformity can be achieved by overlaying different illumination channels.

The illumination of the entrance pupil of the projection optical unit 10 can be defined geometrically by an arrangement of the second facets 23. The intensity distribution in the entrance pupil of the projection optical unit 10 can be set by selecting the illumination channels, for example the subset of the second facets 23, which guide light. This intensity distribution is also referred to as illumination setting or illumination pupil filling.

A likewise preferred pupil uniformity in the region of portions of an illumination pupil of the illumination optical unit 4 that are illuminated in a defined manner can be achieved by a redistribution of the illumination channels.

Further aspects and details of the illumination of the object field 5 and for example of the entrance pupil of the projection optical unit 10 are described below.

For example, the projection optical unit 10 can comprise a homocentric entrance pupil. It can be accessible. It can also be inaccessible.

The entrance pupil of the projection optical unit 10 regularly cannot be exactly illuminated with the second facet mirror 22. In the case of projection optical unit 10 imaging, which images the centre of the second facet mirror 22 telecentrically onto the wafer 13, the aperture rays often do not intersect at a single point. However, it is possible to find an area in which the spacing of the aperture rays that is determined in pairs becomes minimal. This area represents the entrance pupil or an area in real space that is conjugate thereto. For example, this area exhibits a finite curvature.

It may be the case that the projection optical unit 10 has different positions of the entrance pupil for the tangential beam path and for the sagittal beam path. In this case, an imaging element, for example an optical component part of the transfer optical unit, should be provided between the second facet mirror 22 and the reticle 7. With the aid of this optical element, the different positions of the tangential entrance pupil and the sagittal entrance pupil can be taken into account.

In the arrangement of the components of the illumination optical unit 4 illustrated in FIG. 1, the second facet mirror 22 is arranged in an area conjugate to the entrance pupil of the projection optical unit 10. The first facet mirror 20 is arranged tilted in relation to the object plane 6. The first facet mirror 20 is arranged tilted in relation to an arrangement plane defined by the deflection mirror 19. The first facet mirror 20 is arranged tilted in relation to an arrangement plane defined by the second facet mirror 22.

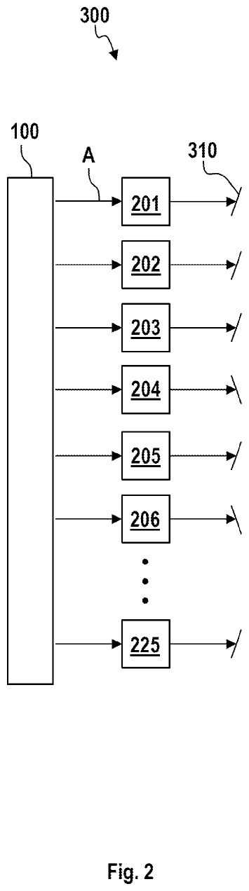

FIG. 2 shows a schematic illustration of an embodiment of an optical system 300 for a lithography apparatus or projection exposure apparatus 1, as shown in FIG. 1 for example. Additionally, the optical system 300 of FIG. 2 may also be used in a DUV lithography apparatus for example.

The optical system 300 of FIG. 2 has a plurality of actuatable optical elements 310. The optical system 300 is designed here as a micromirror array, wherein the optical elements 310 are micromirrors. Each micromirror 310 is actuatable via an assigned actuator 201-225. For example, a respective micromirror 310 can be tilted about two axes and/or displaced in one, two, or three spatial axes via the assigned actuator 201. The reference signs only of the topmost row of these elements are depicted, for reasons of clarity. In embodiments, a plurality of actuators 201-225 may also actuate a single optical element 310.

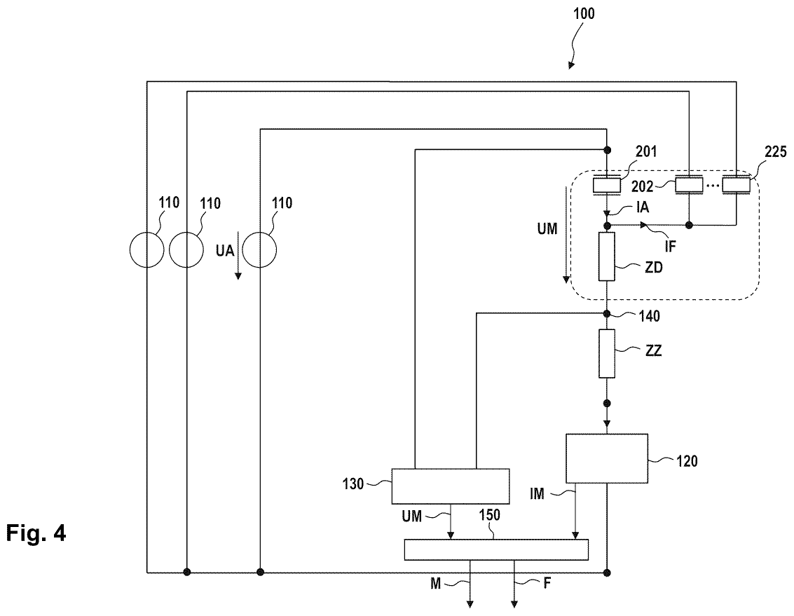

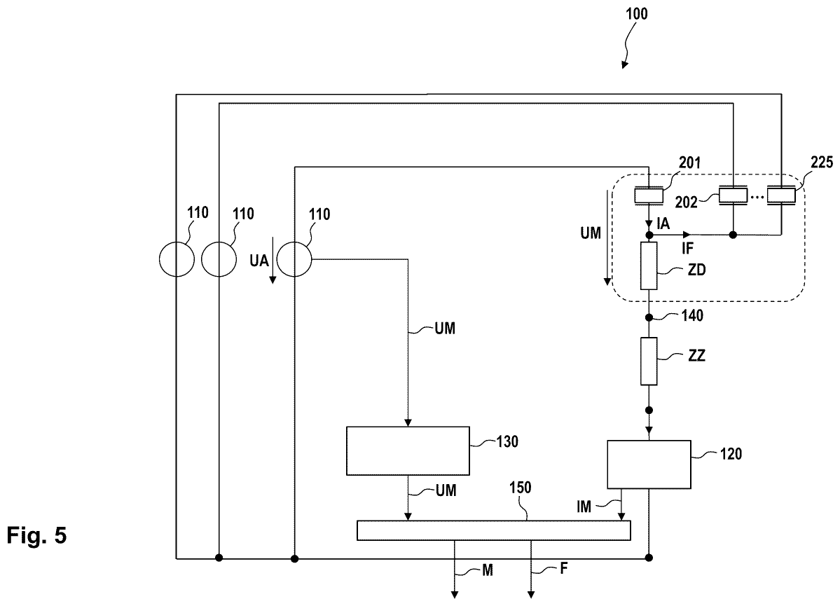

The control device 100 controls the respective actuator 201-225, for example with a control voltage A. This sets a position of the respective micromirror 310. The control device 100 is described with reference to FIGS. 4 and 5 for example.

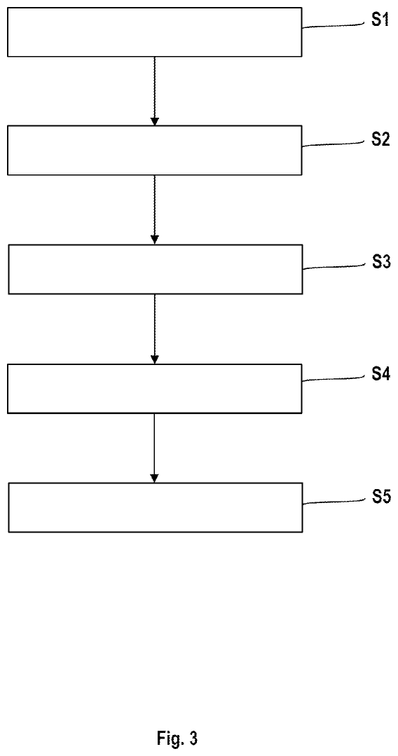

FIG. 3 illustrates a schematic view of an embodiment of a method for controlling and measuring a plurality N of actuators 201-225 for actuating at least one optical element 310 of an optical system 300. Without loss of generality, N=25 in FIGS. 3 to 6.

An example of an optical system 300 is depicted in FIG. 2. For example, the optical system 300 is a part of a lithography apparatus 1, as depicted in FIG. 1 for example. The method according to FIG. 3 is implementable, for example, by a control device 100 as shown by way of example in FIG. 4 or in FIG. 5. In the method according to FIG. 3, an individual actuator to be measured from the N actuators 201-225, the actuator 201 in FIG. 3, is measured during a specific measurement time interval.

Measuring the actuator 201 to be measured during the measurement time interval comprises steps S1-S5 of FIG. 3. In this case, the method of FIG. 3 is explained with reference to FIG. 4. In this context, FIG. 4 shows a first embodiment of a control device 100 for controlling and measuring the N actuators 201-225 for actuating at least one optical element 310 of an optical system 300.

As shown in FIG. 4, the control device 100 of FIG. 4 has a respective control unit 110 for the respective actuator 201-225, a current measuring unit 120, a voltage measuring unit 130, a common negative electrode 140 connecting the N actuators 201-225, and a controller 150. In this case, the controller 150 is configured to control the measurement of the individual actuator 200 to be measured from the N actuators 201-225 during the specific measurement time interval.

As explained above, a respective control unit 110 is provided for the respective actuator 201-225. The control units 110 are controllable by the controller 150. For the present example of measuring the actuator 201, the control unit 110 depicted to the right in FIG. 4 is configured to excite, via an excitation voltage UA, the actuator 201 to be measured. The current measuring unit 120 is configured to provide a measurement current IM indicative of a time-dependent current IA of the actuator 201 excited via the excitation voltage UA. The voltage measuring unit 130 is configured to provide a measurement voltage UM indicative of a time-dependent voltage of the actuator 210 excited via the excitation voltage UA.

As shown in FIG. 4, the current measuring unit 120 is coupled between the negative electrode 140 of the N actuators 201-225 and the N control units 110 for the N actuators 201-225. In the embodiment of FIG. 4, the voltage measuring unit 130 for providing the measurement voltage UM is connected in parallel with the actuator 200 to be measured.

The controller 150 is configured to control that the N−1 further actuators of the N actuators 201-225, the actuators 202-225 in the present example, are kept at a specific voltage level while the actuator 201 to be measured is excited via the excitation voltage UA. The controller 150 is further configured to ascertain an impedance measurement result M on the basis of the provided measurement current IM and the provided measurement voltage UM and determine a deviation indicative of a fault F in the control device 100 on the basis of the ascertained impedance measurement result M.

Moreover, ZD denotes the impedance of a potential defect in the control device 100 between the output of the actuators 201-225 and the common electrode 140, and ZZ denotes the impedance of the feed line, which connects the common electrode 140 to the current measuring unit 120. Further, IF denotes a fault current which flows in the direction of the further actuators 202-205 from the node connecting the actuator 201 to be measured and the impedance ZD when the actuator 201 is measured.

Returning to the flowchart of FIG. 3, the actuator 201 to be measured can be measured during the measurement time interval by way of steps S1-S5, as follows:

In step S1, the actuator 201 to be measured is excited via the excitation voltage UA provided by the control unit 110.

In step S2, the measurement current IM indicative of the time-dependent current IA of the actuator 201 excited via the excitation voltage UA is provided by the current measuring unit 120.

In step S3, a measurement voltage UM indicative of the time-dependent voltage of the actuator 201 excited via the excitation voltage UA is provided by the voltage measuring unit 130.

During the measurement time interval, and especially while steps S1-S3 are carried out in the process, the N−1 further actuators 202-225 from the N actuators 201-225 are kept at a specific voltage level. In other words, the N−1 further actuators 202-225 are kept at the specific voltage level, at least while the actuator 201 to be measured is excited via the excitation voltage UA. For example, the specific voltage level is a specific hold voltage. In this case, the N−1 further actuators 202-225 are kept at the specific hold voltage while the actuator 201 to be measured is excited via the excitation voltage UA. The specific hold voltages of the N−1 further actuators 202-225 can be identical.

In embodiments, the specific voltage level can also be a reference potential (also referred to as ground or earth). Then, the N−1 further actuators 202-225 are short-circuited while the actuator 201 to be measured is excited via the excitation voltage UA. Measuring the actuator 201 to be measured, especially in accordance with steps S1-S3, can be carried out during the ongoing operation of the optical system 300.

In step S4, an impedance measurement result M is ascertained on the basis of the provided measurement current IM and the provided measurement voltage UM.

In step S5, a deviation indicative of a fault F in the control device 100 is determined on the basis of the ascertained impedance measurement result M. As shown by way of example in FIG. 4, the controller 150 can be configured to provide both the impedance measurement result M and the fault F on the output side, especially for further processing purposes.

An alternative embodiment of the control device 100 is illustrated in FIG. 5. In this case, the control device 100 according to FIG. 5 differs from the control device 100 according to FIG. 4 in terms of the arrangement of the voltage measuring unit 130.

As shown in FIG. 5, the voltage measuring unit 130 of FIG. 5 is coupled to the control unit 110 associated with the actuator 201 to be measured. In this case, the voltage measuring unit 130 is configured to derive, from the excitation voltage UA provided by the control unit 110, the measurement voltage UM for ascertaining the impedance measurement result M.

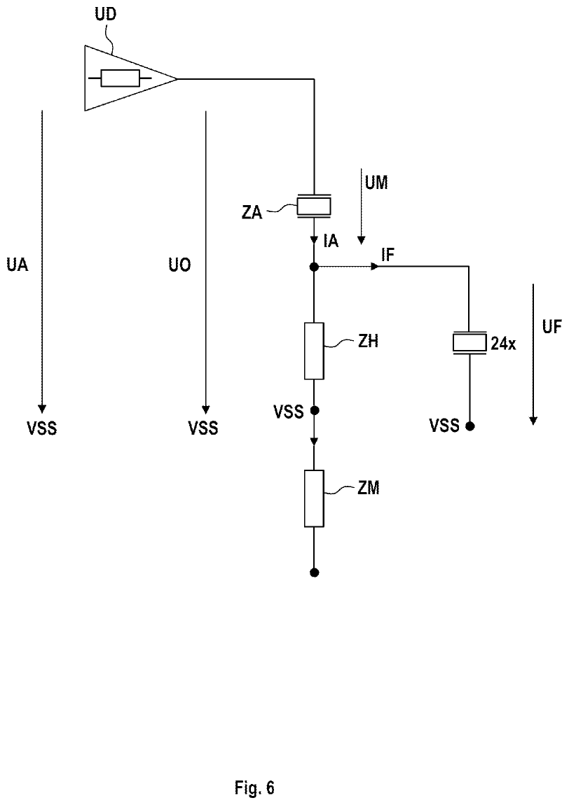

Moreover, FIG. 6 shows a small signal equivalent circuit diagram of an embodiment of a control device 110 as depicted in FIG. 4 or FIG. 5 for example.

In FIG. 6, UA denotes the excitation voltage, UO denotes an output voltage, UD denotes a difference voltage, UM denotes the measurement voltage, UF denotes a fault voltage, ZH denotes an impedance arising from the sum of ZD (impedance of the defect) and ZZ (impedance of the feed line) (see FIGS. 4 and 5), ZM denotes the impedance of the shunt of the current measuring unit 120, IA denotes the time-dependent current of the actuator 201 to be measured, and VSS denotes reference potential (earth potential).

As already explained with reference to FIGS. 4 and 5, the current measuring unit 120 (cf. ZM in FIG. 6) is situated at the common negative electrode 140 of the actuators 201-225. Since all actuators 201-225 share the negative electrode 140, a fault current IF flows into the further N−1 actuators 202-225 and is not captured by the measurement. The outputs of all further actuators 202-225 (represented by 24× in FIG. 6) are referenced to VSS.

The small signal equivalent circuit diagram of FIG. 6 is based on two assumptions. Firstly, the source impedance at the excitation frequency is small enough for a small signal formalism and, secondly, ZA is virtually the same in relation to the further 24 actuators. Hence, the small signal formalism arises as follows:

$$IA = \frac{UM}{ZA} ; IF = \frac{UF}{ZA / 24} = \frac{UF \cdot 24}{ZA} \\ IA = IM + IF \\ \frac{UM}{ZA} = \frac{UF \cdot 24}{ZA} + IM \\ UM = UF \cdot 24 + IM \cdot ZA \\ UF = IM \cdot ZH \\ UM = IM \cdot ZH \cdot 24 + IM \cdot ZA \\ \frac{UM}{IM} = ZA + ZH \cdot 24 \\ ZF = ZH \cdot 24$$

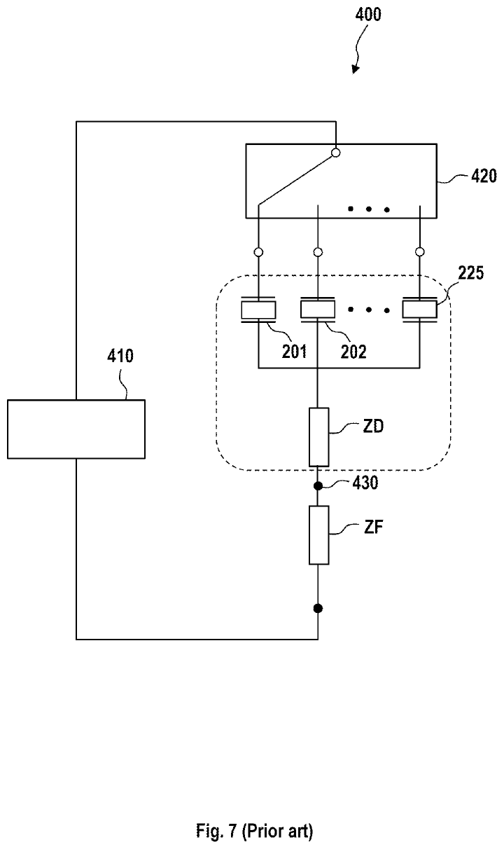

As shown by the equation above, the impedance of the feed line is incorporated as an error 24-times in the measurement during the impedance measurement. In this exemplary embodiment, the impedance measurement of the actuator 201 to be measured is more sensitive to change, for example in the feed line impedance ZH, by a factor of 24 as a result. The relationship of the factor of 24× more sensitive arises for example in comparison with the conventional control device according to FIG. 7, in which the N−1 further actuators 201-225 are not contacted.

Although the present disclosure has been described on the basis of exemplary embodiments, it can be modified in various ways.

### LIST OF REFERENCE SIGNS

1 Projection exposure apparatus
2 Illumination system
3 Light source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
100 Control device
110 Control unit
120 Current measuring unit
130 Voltage measuring unit
140 Negative electrode
150 Controller
201-225 Actuator
300 Optical system
310 Optical element
400 Control device
410 Control unit
420 Switching matrix
430 Electrode
A Control voltage
DU Difference voltage
F Fault
IA Time-dependent current of the actuator to be measured
IF Fault current
IM Measurement current
M Impedance measurement result
M1 Mirror
M2 Mirror
M3 Mirror
M4 Mirror
M5 Mirror
M6 Mirror
S1 Method step
S2 Method step
S3 Method step
S4 Method step
S5 Method step
UF Fault voltage
UO Output voltage
UM Measurement current
VSS Reference potential
ZA Impedance of the actuator to be measured
ZD Impedance of a defect in the control device
ZH Impedance of the sum of ZD and ZZ
ZM Impedance of the shunt
ZZ Impedance of the feed line

What is claimed is:

1. A method of operating a control device configured to control N actuators configured to actuate at least one optical element of an optical system, the N actuators comprising a first actuator and N−1 further actuators, the method comprising:
measuring the first actuator during a measurement time by exciting the first actuator with an excitation voltage provided by a control unit of the control device;
while exciting the first actuator with the excitation voltage, keeping each of the N−1 further actuators at a voltage level;
providing, by a measuring unit of the control device, a measurement current indicative of a time-dependent current of the first actuator;
providing, by a voltage unit of the control device, a measurement voltage indicative of a time-dependent voltage of the first actuator;
determining an impedance measurement result based on the measurement current and the measurement voltage; and
determining a deviation indicative of a fault in the control device based on the impedance measurement result.

2. The method of claim 1, comprising measuring the first actuator while operating the optical system.

3. The method of claim 1, wherein, for each of the N−1 actuators, the voltage level is a hold voltage.

4. The method of claim 3, wherein the hold voltage is the same for each of the N−1 further actuators.

5. The method of claim 1, comprising, while exciting the first actuator with the excitation voltage, short-circuiting the N−1 further actuators.

6. The method of claim 1, wherein the N actuators are connected at a common negative electrode.

7. The method of claim 6, wherein each of the N actuators has a respective control unit, and the current measuring unit is coupled between the negative electrode the control units.

8. The method of claim 6, wherein an actuator pad comprises the N actuators and the common negative electrode.

9. The method of claim 1, wherein the voltage measuring unit is connected in parallel with the first actuator.

10. The method of claim 1, wherein the voltage measuring unit is coupled with the control unit.

11. One or more machine-readable hardware storage devices comprising instructions that are executable by one or more processing devices to perform operations comprising the method of claim 1.

12. A system, comprising:
one or more processing devices; and
one or more machine-readable hardware storage devices comprising instructions that are executable by one or more processing devices to perform operations comprising the method of claim 1.

13. A method of operating a control device configured to control N actuators configured to actuate at least one optical element of an optical system, the N actuators comprising a first actuator and N−1 further actuators, the method comprising:
measuring the first actuator during a measurement time by exciting the first actuator with an excitation voltage provided by a control unit of the control device;
while exciting the first actuator with the excitation voltage, keeping each of the N−1 further actuators at a voltage level; and
determining a deviation indicative of a fault in the control device based on an impedance measurement result,
wherein:
the impedance measurement result is based: i) on a measurement current indicative of a time-dependent current of the first actuator; and ii) a measurement voltage indicative of a time-dependent voltage of the first actuator;
the measurement current is provided by a measuring unit of the control device; and
the measurement voltage is provided by a voltage unit of the control device.

14. One or more machine-readable hardware storage devices comprising instructions that are executable by one or more processing devices to perform operations comprising the method of claim 13.

15. A system, comprising:
one or more processing devices; and
one or more machine-readable hardware storage devices comprising instructions that are executable by one or more processing devices to perform operations comprising the method of claim 13.

16. A control device configured to control and measure N actuators configured to actuate at least one optical element of an optical system, the N actuators comprising a first actuator and N−1 further actuators, the control device comprising:
a controller configured to control a measurement of the first actuator during a measurement time interval;
a control unit controlled by the controller, the control unit configured to excite the first actuator with an excitation voltage;
a current measuring unit configured to provide a measurement current indicative of a time-dependent current of the first actuator; and
a voltage measuring unit configured to provide a measurement voltage indicative of a time-dependent voltage of the first actuator,
wherein the controller is configured to:
keep each of the N−1 further actuators at respective voltage level while the first actuator is excited with the excitation voltage;
determine an impedance measurement result based on the measurement current and the measurement voltage; and
determine a deviation indicative of a fault in the control device based on the impedance measurement result.

17. The control device of claim 16, further comprising a common negative electrode, wherein the N actuators are connected at the common negative electrode.

18. An optical system, comprising:
at least one optical element; and
a control device according to claim 16.

19. The optical system of claim 18, wherein the optical system is an illumination optical unit of a lithography apparatus, or the optical system is a projection optical unit of a lithography apparatus.

20. An apparatus, comprising:
an illumination optical unit; and
a projection optical unit,
wherein:
the apparatus is a lithography apparatus; and
a member selected from the group consisting of the illumination optical unit and the projection optical unit comprises at least one optical element and a control device according to claim 16.
